(19) United States
(12) Patent Application Publication
(10) Pub. No.: US 2006/0060839 A1
(43) Pub. Date: Mar. 23, 2006

(54) Organic semiconductor composition

(76) Inventors: Edwin Arthur Chandross, Murray Hill, NJ (US); Howard Edan Katz, Summit, NJ (US); Elsa Reichmanis, Westfield, NJ (US); Subramanian Vaidyanathan, New Providence, NJ (US)

Correspondence Address: Lucent Technologies Inc.;Docket Administrator, Room 3J-219, 101 Crawfords Corner Road, Holmdel, NJ, 07733-3030, US

(21) Appl. No.: 11/021,586

(22) Filed: Dec. 23, 2004

Related U.S. Application Data
(60) Provisional application No. 60/612,027, filed on Sep. 22, 2004.

(51) Int. Cl. H01L 29/08

(52) U.S. Cl. 257/40

(57) ABSTRACT

A solid semiconductor composition includes a solid matrix of organic semiconductor molecules and a dispersion of nanorods or nanotubes in the matrix. The nanorods or nanotubes do not form a percolating structure that spans the composition.

This application claims the benefit of U.S. Provisional Application No. 60/612,027, filed on Sep. 22, 2004.

### BACKGROUND

1. Field of the Invention

The invention relates to organic semiconductor compositions, methods for making such compositions, and devices incorporating such compositions.

2. Discussion of the Related Art

Thin films of organic semiconductors are frequently polycrystalline and thus, are often formed of individual crystals or grains. In a polycrystalline semiconductor, individual grains are separated by grain boundary regions. The grain boundary regions typically have lower conductivities than interior portions of the grains. For that reason, grain boundary regions often cause an organic semiconductor film to have a lower conductivity or transconductivity than a single crystal of the same organic semiconductor.

### BRIEF SUMMARY

In one aspect, the invention features a solid semiconductor composition that includes a solid matrix of organic semiconductor molecules and a dispersion of nanorods or nanotubes in the matrix. The nanorods or nanotubes do not form a percolating structure that spans the composition.

In another aspect, the invention features a method for fabricating a solid semiconductor composition. The method includes providing a mixture including organic semiconductor molecules or precursors for such molecules. The mixture also includes a solvent and either nanotubes or nanorods that are dispersed in the solvent. The method includes heating the mixture to evaporate the solvent and form the solid semiconductor composition. The nanotubes or nanorods do not form a percolating structure that spans the solid semiconductor composition.

Some embodiments include a transistor having a semiconducting layer, drain and source electrodes in contact with the semiconducting layer, a dielectric layer adjacent a channel portion of the semiconducting layer, and a gate electrode. The channel portion extends between the drain and source electrodes. The gate electrode is located to control the channel portion. The dielectric layer is interposed between the gate electrode and the semiconducting layer. The semiconducting layer includes a solid matrix of organic semiconductor molecules and nanorods or nanotubes that are dispersed in the matrix. The dispersed nanorods or nanotubes do not form a percolating structure that spans the semiconducting layer.

### BRIEF DESCRIPTION OF THE DRAWINGS

FIG. 1 shows a polycrystalline semiconductor composition;

FIG. 2 shows an amorphous solid semiconductor composition;

FIG. 3 is a flow chart illustrating a method for fabricating the solid semiconductor compositions of FIGS. 1 and 2;

FIG. 4 shows a precursor for pentacene used in some embodiments of the method of FIG. 3;

FIG. 5 is a flow chart illustrating a method for fabricating an exemplary composition according to FIG. 1 or 2 with 5,5′-bis(4-hexylphenyl)-2,2′-bithiophene;

FIG. 6 shows the molecule for 5,5′-bis(4-hexylphenyl)-2,2′-bithiophene as used in the method of FIG. 4;

FIG. 7 shows a thin film field-effect transistor whose active channel incorporates one of the solid organic semiconductor compositions of FIGS. 1-2.

Herein, like reference numbers indicate functionally similar molecules or structures.

The illustrative embodiments are described more fully by the Figures and detailed description. The inventions may, however, be embodied in various forms and are not limited to embodiments described in the Figures and detailed description.

### DETAILED DESCRIPTION OF ILLUSTRATIVE EMBODIMENTS

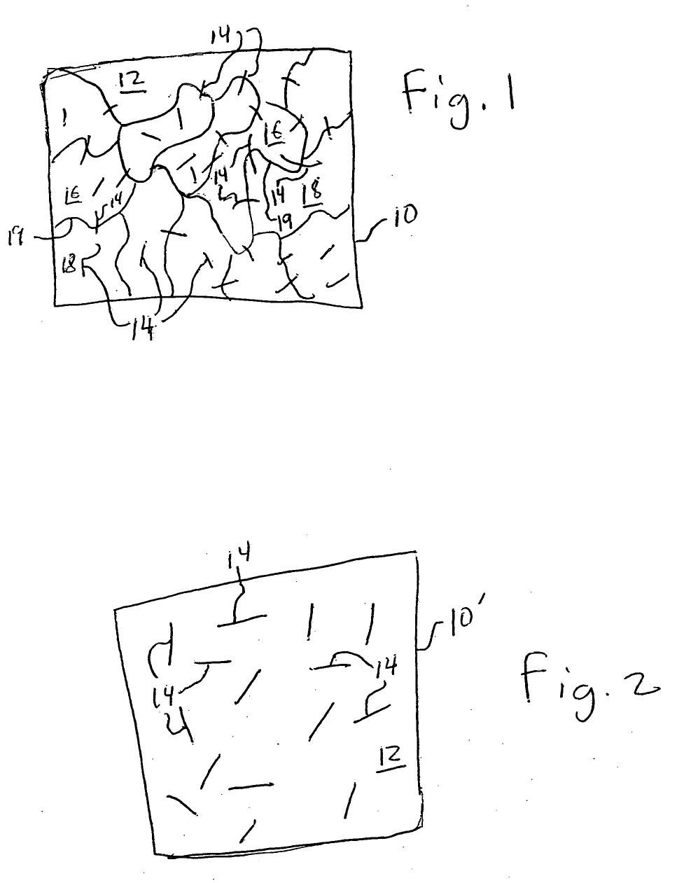

FIGS. 1 and 2 show solid semiconductor compositions 10, 10′. The compositions 10, 10′ include a matrix 12 of organic semiconductor molecules and nanorods and/or nanotubes 14 that are dispersed uniformly in the matrix 12. The matrix 12 may include a single type of organic semiconductor molecule or a mixture of more than one type of semiconductor molecule. Such mixtures may provide improved properties to the matrix 12, e.g., larger grain sizes or better adhesion properties. The nanorods and/or nanotubes 14 are randomly distributed in the matrix 12 to form a substantially unordered dispersion therein. Typically, orientations vary substantially randomly for adjacent ones of the nanorods and/or nanotubes 14. Nevertheless, the nanorods and/or nanotubes do not form a continuous structure that spans the composition.

Referring to FIG. 1, polycrystalline matrix 12 includes a plurality of crystalline grains 16, 18. Adjacent ones of the grains 16, 18 are separated by grain boundary regions 19. Some of the nanorods and/or nanotubes 14 form bridges across the boundary regions 19 between adjacent ones of the grains 16, 18.

In various embodiments, the nanorods and/or nanotubes 14 have different electrical properties. The individual nanorods and/or nanotubes 14 may be electrically conducting, electrically semiconducting, or electrically insulating.

Referring to FIG. 2, the solid semiconductor composition 10′ has a matrix 12 of organic semiconductor molecules that is substantially homogenous and amorphous rather than being polycrystalline.

Referring to FIGS. 1 and 2, the matrix 12 of the compositions 10, 10′ may include one or more of species of organic semiconductor molecule. Exemplary species include regioregular poly(3-hexylthiophene), which is commercially available from Sigma-Aldrich Company (www.sigmaaldrich.com); poly(9,9-dioctylfluorenylbithiophene), which is known as F8T2 and is commercially available from Dow Chemical Company (www.dow.com); and 5,5′-bis(4-hexylphenyl)-2,2′-bithiophene (Herein, referred to as 6PTTP6). The semiconducting compound 6PTTP6 may be synthesized according to procedures well-known to those of skill in the art. See, e.g., the article by Mushrush, M.; Facchetti, A.; Lefenfeld, M.; and Katz, H. E.; and Marks T. J., entitled “Easily processable phenylene-thiophene-based organic field-effect transistors and solution-fabricated nonvolatile transistor memory elements”, JOURNAL OF THE AMERICAN CHEMICAL SOCIETY 125 (31): pages 9414-9423, Aug. 6, 2003.

In the compositions 10, 10′, the matrix 12 may also be fabricated of other known organic semiconductor molecules. Exemplary organic semiconductor oligomers and/or semiconductor polymers are described in “High-performance semiconducting polythiophenes for organic thin-film transistors” by Ong B. S., Wu Y. L., Liu P., and Gardner S. at JOURNAL OF THE AMERICAN CHEMICAL SOCIETY 126 (11): pages 3378-3379, Mar. 24, 2004; “Polythiophene-based field-effect transistors with enhanced air stability” by Ong B., Wu Y. L., Jiang L., Liu P., and Murti K. at SYNTHETIC METALS 142 (1-3): pages 49-52, Apr. 13, 2004; “Short channel effects in regioregular poly(thiophene) thin film transistors” by Chabinyc M. L., Lu J. P., Street R. A., Wu Y. L., Liu P., and Ong B. at JOURNAL OF APPLIED PHYSICS 96 (4): pages 2063-2070, Aug. 15, 2004; and “Poly(3,3″-dialkylterthiophene)s: Room-Temperature, Solution-Processed, High-Mobility Semiconductors for Organic Thin-Film Transistors” by Wu Yiliang, Ping Liu, Sandra Gardner, and Beng S. Ong, which is published by the American Chemical Society online at http://pubs.acs.org/journals/cmatex/index.htim under “articles”.

The above-listed articles are incorporated herein by reference in their entirety.

The matrix 12 may have organic semiconductor molecules with structures based on aromatic rings and have conjugation lengths similar to those of the exemplary organic semiconductor molecules described above. These other organic semiconductor molecules may also have side chains of 4-10 carbon atoms. In some of the side chains, an oxygen atom may replace one or more of the carbon atoms. For example, the matrix 12 may include pentacene.

Referring to FIGS. 1 and 2, exemplary nanorods and/or nanotubes 14 include conducting or semiconducting nanowires, conducting or semiconducting carbon nanotubes, and/or metallic wires or nanowires. The examples of semiconducting nanotubes and nanowires are based on carbon or inorganic semiconductors. Methods for making conducting and semiconducting carbon nanowires and/or carbon nanotubes are known to those of skill in the art. Various types of carbon nanotubes may, e.g., also be obtained commercially from Carbon Nanotechnologies Inc., 16200 Park Row, Houston, Tex. 77084-5195 USA (Herein, referred to as CNI.).

For embodiments in which the nanorods and/or nanotubes 14 are conducting or semiconducting, the density of said nanorods and/or nanotubes 14 is lower than the threshold where a random dispersion of the nanorods and/or nanotubes 14 would form a percolation structure. Herein, a percolation structure is a connected structure that spans a non-minimal linear dimension of the entire composition, e.g., the composition 10, 10′. Herein, a non-minimal linear dimension is a linear dimension of the solid composition that is not the solid composition's smallest linear dimension, e.g., a layer thickness is the minimal dimension of a thin layer. For densities below the percolation threshold, the nanorods and/or nanotubes 14 do not form a conducting or semiconducting network that could short-circuit the matrix 12 when the compositions 10, 10′ are used as channels of organic transistors or other electronic devices. Also, in the compositions 10, 10′ the nanorods and/or nanotubes 14 are randomly oriented, e.g., neighboring nanorods and/or nanotubes 14 often have very different orientations.

Herein, nanorod and nanotube refers to a structure with an approximately cylinder-like shape and a diameter of 0.1 micrometers (μm) or less and preferably of 0.01 μm or less. Also, a nanorod and/or nanotube has a length that is, at least, twice as long as its width. The lengths of the nanorods and/or nanotubes may be much larger. Exemplary lengths may be in the range of about 0.01 μm to about 1.0 μm. A nanorod or nanotube may be straight, bent, or twisted along its axis and may have a circularly cylindrical or an oval-shaped cross section.

Preferably, the nanorods and/or nanotubes are sufficiently long to bridge high-mobility domains of the matrix, e.g., long enough to electrically connect adjacent ones of the crystals. In embodiments where the nanorods and/or nanotubes are conductive or semiconductive, they can form bridges that electrically short boundary regions thereby compensating for the otherwise low conductivities of said regions. The nanorods and nanotubes are not long enough to themselves form a percolating cluster across the whole composition 10, 10′.

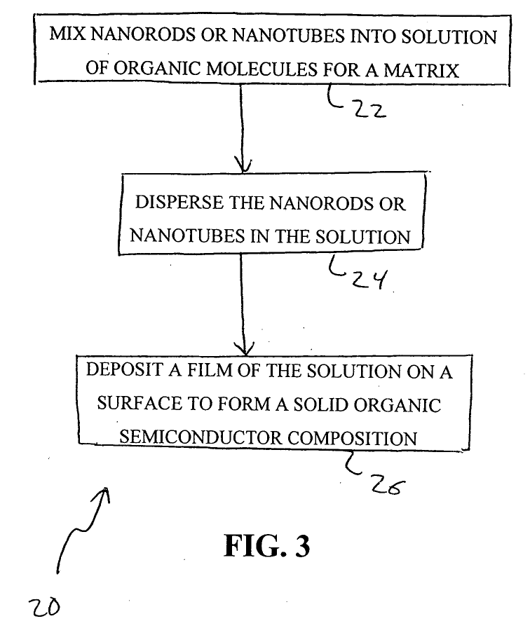

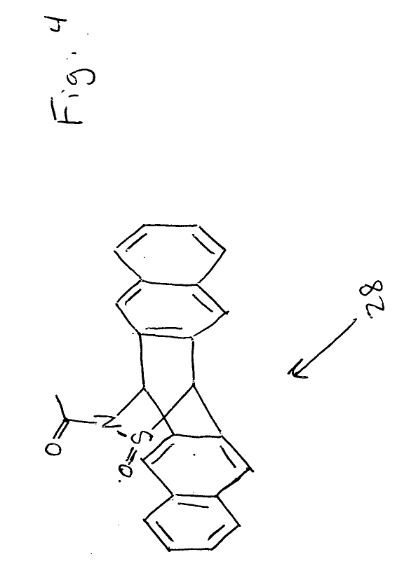

FIG. 3 shows a method 20 of making the solid semiconductor compositions 10, 10′ of FIGS. 1 and 2.

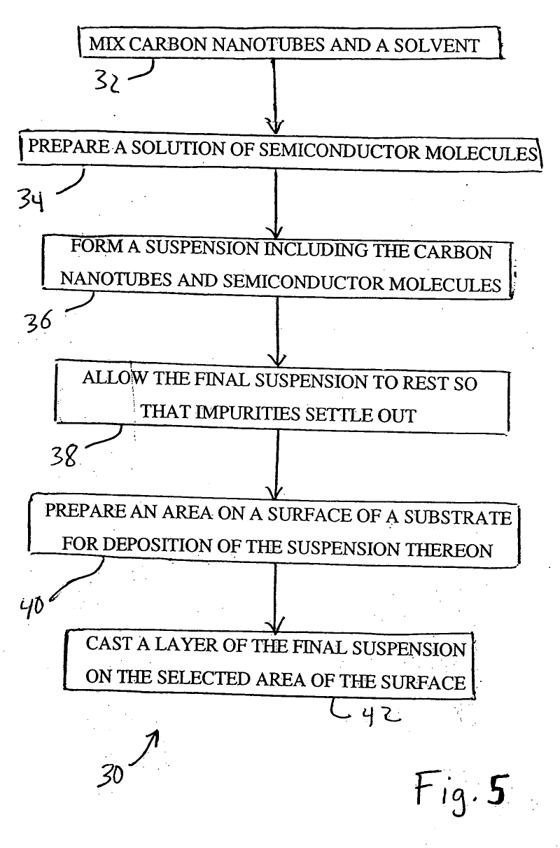

First, the method 20 includes mixing the nanorods and/or nanotubes 14 into a solution of organic molecules for the matrix 12 (step 22). The organic molecules are either organic semiconductor molecules or precursors for organic semiconductor molecules. Exemplary precursor molecules include soluble precursors of pentacene, e.g., the Diels-Alder adduct 28 of FIG. 4. The synthesis of the Diels-Alder adduct 28 is known to those of skill in the art, and is, e.g., described in the article “High-Performance, Solution-Processed Organic Thin Film Transistors from a Novel Pentacene Precursor”, by Ali Afzali, Christos D. Dimitrakopoulos, and Tricia L. Breen, Journal of American Chemical Society (JACS), vol. 124 (2002) pages 8812-8813, which is incorporated herein by reference in its entirety. The mixing step includes dissolving the molecules for the matrix 12 in a suitable solvent, e.g., an organic solvent. Prior to the mixing step, external surfaces of the nanorods and/or nanotubes 14 may also be chemically functionalized by known processes to increase their compatibility with the solvent thereby increasing their ability to disperse in the solvent. Any such chemical functionalization should not substantially interfere with conductivity properties of the nanorods and/or nanotubes or conductivity properties between the nanorods and/or nanotubes 14 and the organic molecules for the matrix 12.

Second, the method 20 includes performing ultrasonication of the liquid mixture to disperse the nanorods and/or nanotubes substantially uniformly in the solvent (step 24). The ultrasonication is performed at power settings low enough to not break semiconductor molecules of precursors therefore or nanorods or nanotubes.

Third, the method 20 includes forming a semiconducting film or body from the liquid mixture on a planar surface of a substrate (step 26). Exemplary forming steps may include casting, inkjet printing, or spin-coating the liquid mixture onto the planar surface. Such methods for forming thin films are well known to those of skill in the art.

If the liquid mixture includes a precursor for an organic semiconductor the method 20 includes a treatment step that converts the precursor molecules into organic semiconductor molecules. For the above-described precursor of pentacene, an exemplary treatment step may include heating the film that remains after the solvent has evaporated from the liquid mixture. For example, heating the film to about 250° C. stimulates a reaction that converts the above-described precursor molecules into insoluble pentacene. The resulting film will typically be more resistant to intermixing during any subsequent solution deposition of material on the solid organic semiconductor composition.

### EXAMPLE

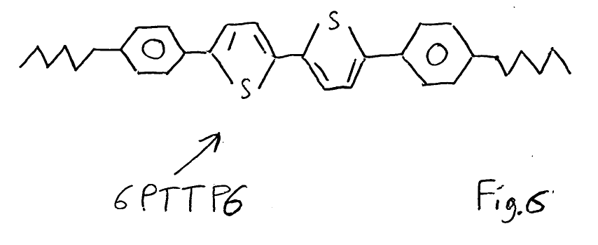

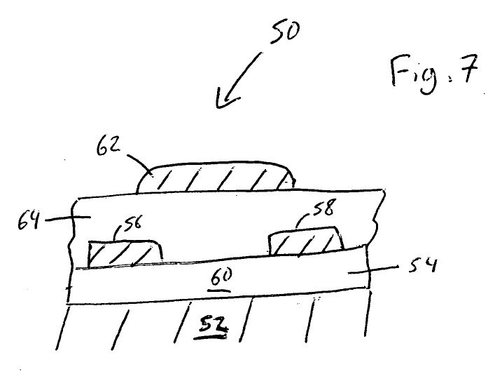

FIG. 5 illustrates an exemplary method 30 for fabricating a layer with a solid semiconductor composition 10, 10′ that includes carbon nanotubes and a matrix 12 of 6PTTP6 molecules. FIG. 6 illustrates a 6PTTP6 molecule.

The method 30 includes mixing a commercial preparation of insulating, conducting, and/or semiconducting carbon nanotubes into a liquid solvent to produce a suspension of the carbon nanotubes (step 32). An exemplary suspension includes about 1 milligram of the carbon nanotubes in about 1.0 grams of the solvent xylene. Commercial preparations of carbon nanotubes are, e.g., available as single wall carbon nanotubes from CNI. Such preparations also typically include amorphous carbon impurities. After performing the mixing, an ultrasonication of several hours, e.g., 12 hours, disperses the carbon nanotubes uniformly and randomly in the solvent. Preferably, the ultrasonication is performed in a manner that does not physically damage the carbon nanotubes. In exemplary embodiments, a model PC3 sonicator of the L & R Ultrasonics Company (www.lrultrasonics.com) was operated at 55 kilohertz and a 22-watt power setting during the ultrasonication.

The method 30 also includes preparing a solution of a selected organic semiconductor oligomer, i.e., 6PTTP6 (step 34). An exemplary solution is formed by mixing about 1 milligram of 6PTTP6, in about 2.5 grams of xylene.

The method 30 includes forming a final suspension of the carbon nanotubes and 6PTTP6 molecules by mixing selected amounts of the suspension from step 32 and the solution from step 34 (step 36). The selected amounts are determined by the desired value for the ratio of the weight percentage (wt %) of carbon nanotubes over the wt % of organic semiconductor oligomers in the final suspension. In exemplary final suspensions, this ratio has a value in the range of about 0.01 to about 0.20 and preferably has a value in the range of about 0.01 and about 0.05. After performing the mixing, another ultrasonication of about 12 hours uniformly disperses the carbon nanotubes in the final suspension.

The method 30 includes allowing the final suspension to rest so that impurities from the commercial carbon nanotube preparation, e.g., amorphous carbon, settle out of the final suspension (step 38). Typically, a rest period of about 3 or more hours is sufficient. After the rest period, the clear liquid containing suspended carbon nanotubes and 6PTTP6 is extracted for use in subsequent steps.

The method 30 includes preparing an area on a surface of a dielectric or semiconductor substrate, e.g., crystalline silicon, for subsequent deposition of the final suspension (step 40). The selected area typically includes a boundary that has been functionalized to be hydrophobic, e.g., by one of a variety of fluoro-oligomers. Examples of suitable fluoro-oligomers include the FC722 product and the Novec Electronic Coating EGC 1700 product of 3M Corporation, 3M Center of St. Paul, Minn. 55144-1000 (www.3M.com).

The method 30 also includes casting a thin layer of the final suspension onto the selected area of the surface of the substrate (step 42). The casting involves placing a droplet of the final suspension on the prepared area of the surface so that the hydrophobic boundary constrains the droplet from spreading laterally. The casting also involves heating the substrate to evaporate solvent from the droplet thereby producing a thin solid film on the selected area. The solid film includes the 6PTTP6 organic semiconductor oligomers and the carbon nanotubes. The heating typically makes the 6PTTP6 matrix better ordered and more continuous, e.g., grains are larger and 6PTTP6 molecules are better aligned, providing that bubbles are not produced during the heating. Thus, the heating is performed at a temperature lower than the boiling point for the solvent. For example, heating to about 125° C. is suitable for xylene, which has a boiling point of about 148° C.

Referring to FIGS. 3 and 5, some embodiments of methods 20, 30 also include steps for forming other device structures adjacent to the layer of the solid organic semiconductor composition. For example, the additional steps may include producing gate, source, and drain electrodes of a transistor via conventional deposition processes, e.g., mask-controlled evaporation deposition of metal. The additional steps may also include depositing a layer of organic dielectric adjacent the solid organic semiconductor composition, e.g., to function as a gate dielectric. The deposition of the organic dielectric may, e.g., involve spin coating, casting or inkjet printing a liquid preparation for the organic dielectric and then, solidifying the dielectric. In such deposition steps, the liquid preparation typically includes a solvent that does not dissolve or penetrate the solid organic semiconductor composition.

The solid organic semiconductor compositions 10, 10′ of FIGS. 1 and 2 may be used in a variety of integrated electronic devices.

FIG. 7 shows an organic field-effect transistor (OFET) 50 that incorporates one of the solid organic semiconductor compositions 10, 10′ into a functional transistor structure. In particular, the OFET 50 includes a thin semiconducting layer 54 formed of one of the solid semiconductor compositions 10, 10′ of FIG. 1 or 2. The thin semiconducting layer 54 is located on a dielectric or semiconductor substrate 52. The OFET 50 has conductive source and drain electrodes 56, 58, e.g., metallic electrodes. The source and drain electrodes 56, 58 are in contact with one surface of the thin semiconducting layer 54. The OFET 50 also has a conducting gate electrode 62 and a gate dielectric layer 64, e.g., an organic dielectric. The gate dielectric 64 is in contact with the thin semiconducting layer 54 and the gate electrode 62. The gate electrode 62 is located to enable controlling a channel portion 60 of the thin semiconducting layer 54. The channel portion 60 connects the source and drain electrodes 56, 58.

In the OFET 50, the nanorods and/or nanotubes 14 of the thin semiconducting layer 54 do not produce electrical shorting between the source and drain electrodes 56, 58 or across the thin semiconducting layer 54. In particular, lengths of the nanorods and/or nanotubes 14 are, at least, less than both the length of the channel portion 60 and the thickness of the gate dielectric layer 64, i.e., so that a protruding nanorod or nanotube does not short the gate electrode 62.

From the disclosure, drawings, and claims, other embodiments of the invention will be apparent to those skilled in the art.

What we claim is:

1. A solid composition, comprising:
a solid matrix of organic semiconductor molecules; and
one of nanorods and nanotubes dispersed in the matrix; and
wherein the dispersed one of nanorods and nanotubes do not form a percolating structure that spans the composition.

2. The composition of claim 1, wherein the one of nanorods and nanotubes are conducting or semiconducting.

3. The composition of claim 2, wherein adjacent ones of the one of nanorods and nanotubes are substantially unaligned.

4. The composition of claim 2, wherein the one of nanorods and nanotubes do not form a percolating structure having a linear dimension of 10 micrometer or more.

5. The composition of claim 3, wherein the one of nanorods and nanotubes include one of carbon nanotubes.

6. The composition of claim 3, wherein the one of nanorods and nanotubes are semiconducting or conducting carbon nanotubes.

7. The composition of claim 3, wherein the one of nanorods and nanotubes are metallic wires.

8. The composition of claim 3, wherein the molecules include one of regioregular poly(3-hexylthiophene), poly(9,9-dioctylfluorenylbithiophene), and 5,5′-bis(4-hexylphenyl)-2,2′-bithiophene.

9. The composition of claim 3, wherein the molecules are polymers.

10. The composition of claim 1, wherein the one of nanorods and nanotubes are electrically insulating.

11. A method for fabricating a solid semiconductor composition, comprising:
providing a mixture including one of organic semiconductor molecules and precursors for organic semiconductor molecules, a solvent, and one of nanotubes and nanorods, the one of nanotubes and nanorods being dispersed in the solvent; and
heating the mixture to evaporate the solvent and form the solid semiconductor composition, the one of nanotubes and nanorods not forming a percolating structure spanning the solid semiconductor composition.

12. The method of claim 1 wherein the one of nanotubes and nanorods comprise carbon nanotubes.

13. The method of claim 12, wherein the providing a mixture further comprises removing amorphous carbon impurities from a portion of a suspension of the carbon nanotubes in a solvent.

14. The method of claim 12, wherein the one of nanotubes and nanorods are electrically semiconducting or conducting.

15. A transistor, comprising:
a semiconducting layer;
drain and source electrodes in contact with the semiconducting layer;
a dielectric layer in contact with a channel portion of the semiconducting layer, the channel portion extending between the drain and source electrodes; and
a gate electrode located to control the channel portion, the dielectric layer being interposed between the gate electrode and the semiconducting layer; and
wherein the semiconducting layer further comprises:
a solid matrix of organic semiconductor molecules; and
one of nanorods and nanotubes dispersed in the matrix, the dispersed one of nanorods and nanotubes not forming a structure that spans the distance between the source and drain electrodes.

16. The transistor of claim 15, wherein the one of nanorods and nanotubes are conducting or semiconducting.

17. The transistor of claim 16, wherein adjacent ones of one of the nanorods and nanotubes are substantially not aligned.

18. The transistor of claim 15, wherein the one of nanorods and nanotubes are carbon nanotubes.

19. The transistor of claim 18, wherein the carbon nanotubes are electrically semiconducting or conducting.

20. The transistor of claim 15, wherein the molecules include one of regioregular poly(3-hexylthiophene), poly(9,9-dioctylfluorenylbithiophene), and 5,5′-bis(4-hexylphenyl)-2,2′-bithiophene.
